(19) United States
(12) Patent Application Publication
(10) Pub. No.: US 2005/0280133 A1
(43) Pub. Date: Dec. 22, 2005

(54) Multiple device package

(75) Inventors: Leeshawn Luo, Santa Clara, CA (US); Anup Bhalla, Santa Clara, CA (US); Sik K. Lui, Sunnyvale, CA (US); Yueh-Se Ho, Sunnyvale, CA (US); Mike F. Chang, Cupertino, CA (US); Xiao Tiang Zhang, San Jose, CA (US)

Correspondence Address: VAN PELT, YI & JAMES LLP, 10050 N. FOOTHILL BLVD #200, CUPERTINO, CA, 95014, US

(73) Assignee: Alpha & Omega Semiconductor

(21) Appl. No.: 10/873,743

(22) Filed: Jun. 21, 2004

(51) Int. Cl. H01L 23/495; H01L 21/48

(52) U.S. Cl. 257/686; 257/676; 438/123; 257/692; 257/696

(57) ABSTRACT

A semiconductor package and method of assembling a semiconductor package is disclosed. The semiconductor package includes a first device mounted on a leadframe and a second device mounted on the leadframe. The leadframe has leads extending to the exterior of the package. An anvil may be used to mount a device on the package. The anvil may include two side portions to support the leads of the package, two end portions connected to the two side portions, and a cutout region.

### FIELD OF THE INVENTION

The present invention relates generally to semiconductor devices. More specifically, a multiple device package is disclosed.

### BACKGROUND OF THE INVENTION

A power semiconductor device may be judged by the amount of current it can control per unit area or per unit volume. To increase the current that may flow through the device without damaging or overheating the device, many power MOSFETs typically assume a vertical configuration, with the drain disposed at the bottom of a chip, to allow for more uniform power distribution throughout the device. A typical power MOSFET may include a number of devices connected in parallel on a single chip. Chip packaging designs have been developed to house chips with such a configuration.

FIG. 1 is a diagram illustrating a typical vertical power device package. Chip 102 is mounted on a leadframe 104 and wire bonded to source leads 108 and gate lead 110. Drain leads 112 extend from leadframe 104 to the exterior of the package. To improve power efficiency, efforts have focused on improving silicon technology to lower the resistance per unit area when the device is on and decreasing parasitic resistances incurred from packaging. However, better methods are needed to increase the power efficiency of the device.

### BRIEF DESCRIPTION OF THE DRAWINGS

Various embodiments of the invention are disclosed in the following detailed description and the accompanying drawings.

FIG. 1 is a diagram illustrating a typical vertical power device package.

FIG. 2A is a diagram illustrating a cross section a double sided device package.

FIG. 2B is a diagram illustrating a top view of the double sided device package illustrated in FIG. 2A.

FIG. 2C is a diagram illustrating a cross section of a double sided device package where one device is connected to the lead frame using a conductive material and the other device is not electrically connected to the lead frame.

FIG. 3A is a diagram illustrating a top view of a complementary pair in a double sided device package.

FIG. 3B is a diagram illustrating a bottom view of the complementary pair illustrated in FIG. 3A.

FIG. 4 is a diagram illustrating an anvil that may be used to mount devices onto a double sided device package.

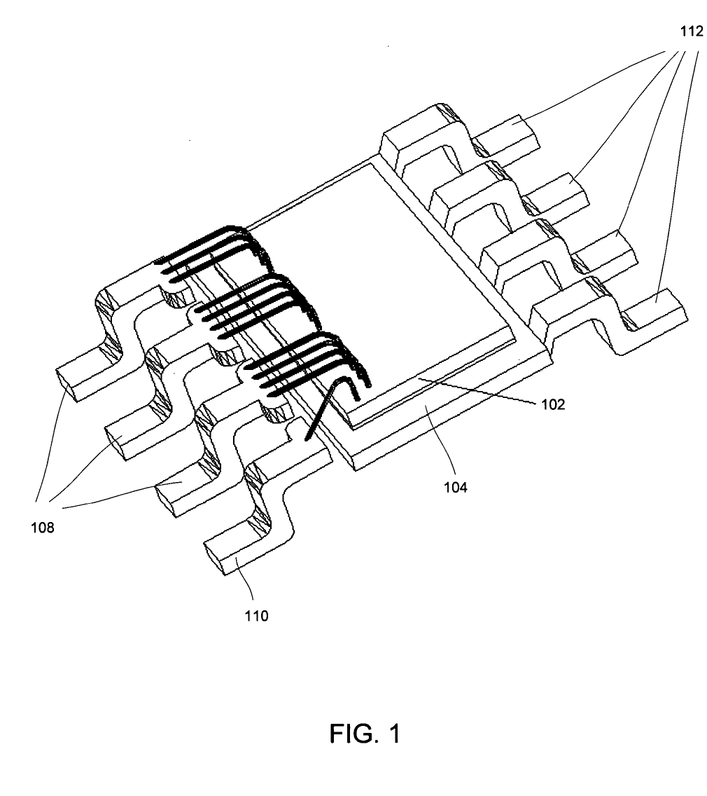

### DETAILED DESCRIPTION

The invention can be implemented in numerous ways, including as a process, an apparatus, a system, a composition of matter, a computer readable medium such as a computer readable storage medium or a computer network wherein program instructions are sent over optical or electronic communication links. In this specification, these implementations, or any other form that the invention may take, may be referred to as techniques. In general, the order of the steps of disclosed processes may be altered within the scope of the invention.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and invention may be practiced according to the claims without some or all of these specific details. For the purpose of clarity, technical material that is known in the technical fields related to the invention has not been described in detail so that the invention is not unnecessarily obscured.

Packaging multiple semiconductor devices on a leadframe may increase the power efficiency of such a combined semiconductor device. For example, a double sided device package may be formed by mounting devices on both sides of a leadframe. The two devices mounted on either side of the leadframe may be connected in parallel to lower the overall resistance of the combined power device that comprises the two devices contained in the package.

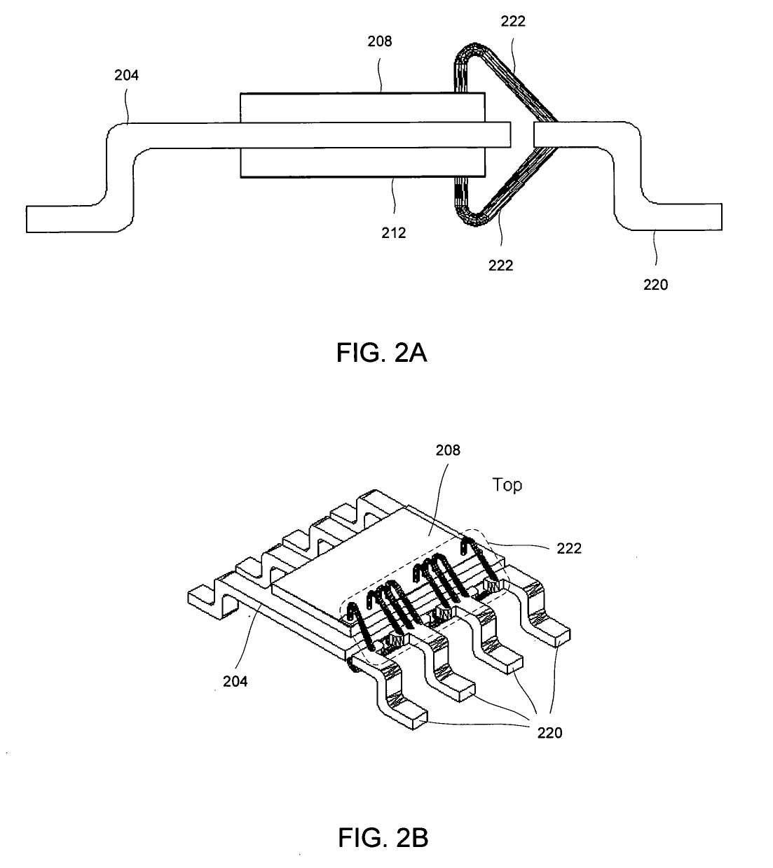

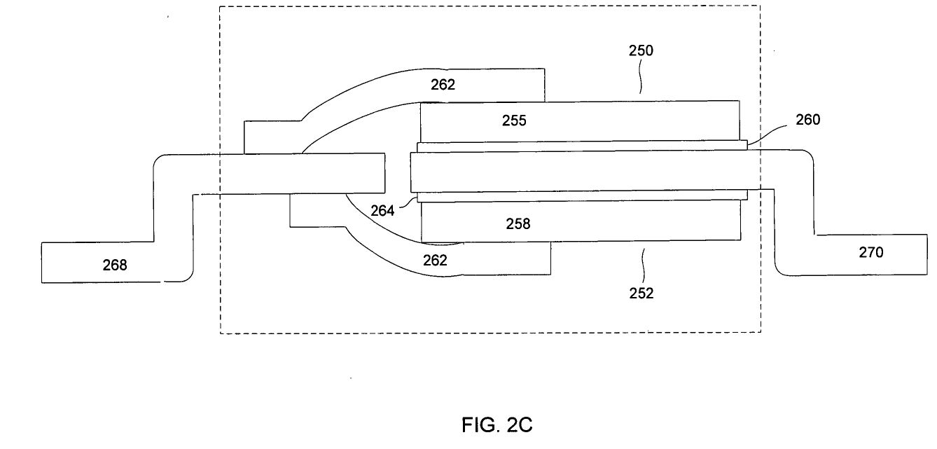

FIG. 2A is a diagram illustrating a cross section a double sided device package. In this example, chip 208 and chip 212 are mounted on opposite sides of a common leadframe 204. The common terminals of each device are connected to the same metal lead. One terminal of each device is attached to leadframe 204, making leadframe 204 a common terminal to both devices. Bonding wires 222 extend from various positions on the edge of each chip to leads 220. In some embodiments, chip 208 and chip 212 are MOSFET chips, where the gate of each device is bonded to a gate lead and the source of each device is bonded to a source lead. The drain terminal of each device is attached to leadframe 204, making leadframe 204 a common drain to both devices. The parallel connection shown enables half the resistance of an individual device combined with half the bonding wire resistance of a single sided device package to be obtained.

FIG. 2B is a diagram illustrating a top view of the double sided device package illustrated in FIG. 2A. The connections made to chip 208 are visible in detail with corresponding connections to chip 212 being made on the opposite side of leadframe 204. Bonding wires 222 extend from various connections on the edge of chip 208 that are connected to the common terminals of parallel connected devices on chip 208. In various embodiments, different numbers of connections may be provided on the edge of chip 208 or connections may be made to other points on chip 208. Although bonding wires are typically used, any appropriate connection from the chip devices to the leads may be used. Any configuration of terminal leads may be selected on any given chip. For example, the outer leads may be connected to sources and the inner leads may be connected to gates if chips 208 and 212 are MOSFET chips. Leads 220 extend to the exterior of the package.

Various types of devices may be attached to each side of the package. For example, packaging two identical devices of the same polarity may result in improved net performance. The two devices may be designed with dual gate pads to ease wire bonding to the gate. Two devices of different sizes and the same polarity are packaged together in some embodiments. Two devices may be connected in parallel by bonding opposite leads in parallel. For example, an n-channel FET (nFET) device may be mounted on one side and a Schottky device may be mounted on the other side to create a Schottky device in parallel with an nFET device. An n-channel FET and p-channel FET may be packaged to form a complementary pair, as further described below.

FIG. 2C is a diagram illustrating a cross section of a double sided device package where one device is connected to the lead frame using a conductive material and the other device is not electrically connected to the lead frame. A device can include a device such as a transistor, or one or more chips. Device 255 is mounted on leadframe 270 using conductive material 260 (or conductive die attach medium). Device 258 is mounted on leadframe 270 using non-conductive material 264. Bonding wires 262 connect leads 268 to appropriate terminals on the devices. For example, if the devices are both MOSFET devices, the source terminals of each device may be bonded to lead 268. In some embodiments, instead of bonding wires, a copper connection or other appropriate type of connection is used.

As shown, the devices do not need to be electrically connected to the leadframe; one device may be fully isolated from the other. For example, device 255 may be a MOSFET or other device, while device 258 may be a thermal sense diode attached by a non-conductive material. The diode may be bonded out to separate leads. Instead of a diode, a gate driver device with its output connected to the gate may be attached using a non-conductive material. Alternatively, two common drain devices may be attached on top and a battery protection device may be attached on the bottom, and all devices attached using a non-conductive material.

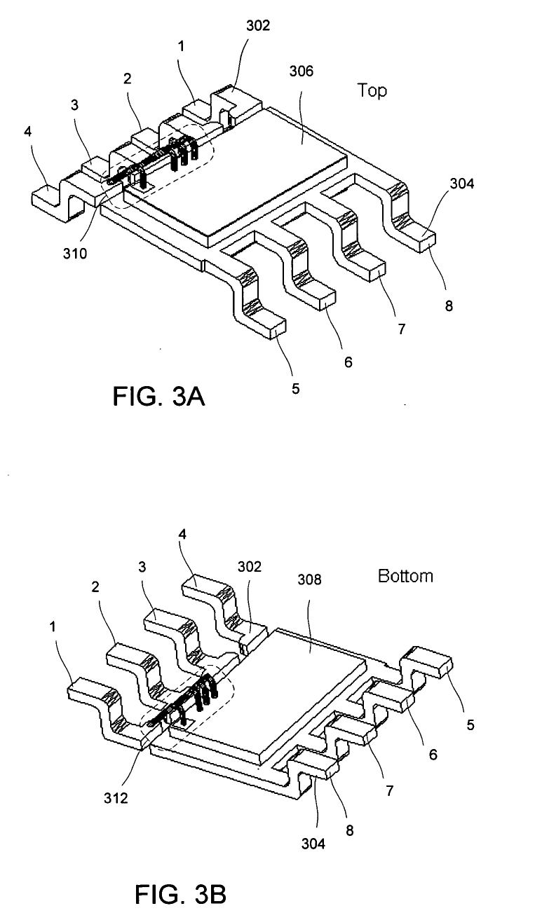

FIG. 3A is a diagram illustrating a top view of a complementary pair in a double sided device package. n-channel FET (nFET) 306 is shown mounted on the top of common drain leadframe 304. Gate and source terminals 310 of nFET 306 are bonded to leads 3-4. FIG. 3B is a diagram illustrating a bottom view of the complementary pair illustrated in FIG. 3A. p-channel FET (pFET) 308 is shown mounted on the bottom of leadframe 304. Gate and source terminals 312 of pFET 308 are bonded to leads 1-2. As shown, common drain leadframe 304 is shared by nFET 306 and pFET 308, but the gate and source terminals of each device are bonded to distinct leads.

Power devices may have thicker bonding wires which may be difficult to attach and require applying significant pressure to the surface of the device. Typical bonding wire widths in a power device are 1-2 mil for gold (Au) wire and 3-18 mil for aluminum (Al) wire. The additional pressure required may induce damage during mounting. Once the first device is installed, a special anvil may be used to allow the leadframe to be flipped and supported without damage while the second device is mounted and bonded.

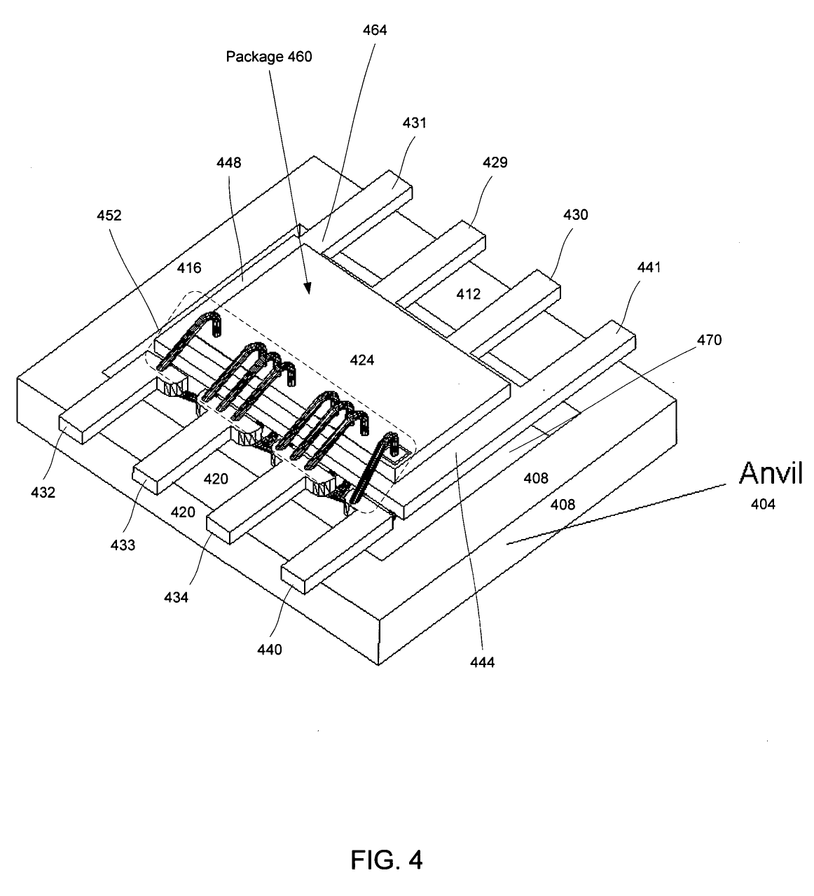

FIG. 4 is a diagram illustrating an anvil that may be used to mount devices onto a double sided device package. In this example, a double sided device package 460 is shown resting on an anvil 404. Double sided device package 460 includes leadframe 464, which includes leads 431, 429, 430, and 441 that extend to the exterior of the package. A top device 424 rests on leadframe 464 and is bonded to leads 432, 433, 434, and 440 by bonding wires 452. Flanges 444 and 448 are portions of leadframe 464 that extend out beyond the ends of device 424. Anvil 404 includes a cutout region 470 so that the bottom device and bonding wires (not shown) on the bottom of the package are not interfered with when top device 424 is mounted and bonding wires 452 are attached to the top of the package. The anvil includes side portions 412 and 420 on opposite sides of cutout 470, and end portions 408 and 416 on opposite ends of cutout 470. In some embodiments, anvil 404 is sized such that end portions 408 and 416 extend further inward towards cutout 470 to support each end of the package, so that leads 440-441 and flange 444 are supported by end portion 408, and leads 431-432 and flange 448 are supported by end portion 416. As shown, anvil 404 and cutout region 470 are rectangular in shape. However, any appropriate shape may be used.

Although the foregoing embodiments have been described in some detail for purposes of clarity of understanding, the invention is not limited to the details provided. There are many alternative ways of implementing the invention. The disclosed embodiments are illustrative and not restrictive.

1. A semiconductor package comprising:
a first device mounted on a leadframe;
wherein the leadframe has leads extending to the exterior of the package; and
a second device mounted on the leadframe.

2. The semiconductor package of claim 1 wherein the first and second devices are mounted on opposite sides of the leadframe.

3. The semiconductor package of claim 1 wherein the first and second devices are electrically connected to the leadframe.

4. The semiconductor package of claim 1 wherein the first device is electrically connected to the leadframe and the second device is not electrically connected.

5. The semiconductor package of claim 1 wherein the first and second devices are electrically connected to the leadframe and electrically connected to each other.

6. The semiconductor package of claim 1 wherein the leadframe is a common drain.

7. The semiconductor package of claim 1 wherein a terminal on the first device is bonded to the same lead as a terminal on the second device.

8. The semiconductor package of claim 1 further including opposite leads connected in parallel.

9. The semiconductor package of claim 1 further including opposite leads that are not connected in parallel.

10. The semiconductor package of claim 1 wherein the first device and the second device have the same polarity.

11. The semiconductor package of claim 1 wherein the first device is an nFET device and the second device is a pFET device.

12. The semiconductor package of claim 1 further including a bonding wire wherein the bonding wire bonds a terminal on the first device to a lead.

13. The semiconductor package of claim 1 further including a gold bonding wire wherein the bonding wire is at least 1 mil thick.

14. The semiconductor package of claim 1 further including an aluminum bonding wire wherein the bonding wire is at least 3 mil thick.

15. The semiconductor package of claim 1 further including a copper connection that bonds a terminal on the first device to a lead.

16. The semiconductor package of claim 1 wherein the first device is a power device.

17. The semiconductor package of claim 1 wherein the first device is a vertical power device. The semiconductor package of claim 1 wherein the first device is an nFET device.

18. The semiconductor package of claim 1 wherein the first device is a Schottky device.

19. The semiconductor package of claim 1 wherein the first device is a thermal sense diode.

20. The semiconductor package of claim 1 wherein the first device is a gate driver device.

21. The semiconductor package of claim 1 further including a third device.

22. The semiconductor package of claim 1 further including a third device wherein:
the first device is a common drain device;
the second device is a common drain device; and
the third device is a battery protection IC.

23. An anvil for mounting a device on a package, comprising:
two side portions to support the leads of a package;
two end portions connected to the two side portions; and
a cutout region.

24. The anvil of claim 24, wherein an end portion extends toward the interior of the anvil to support an end of the package.

25. The anvil of claim 24, wherein both end portions extend towards the interior of the anvil to support both ends of the package.

26. The semiconductor package of claim 1 wherein the first device is mounted using the anvil of claim 23.

27. A method of assembling a semiconductor package comprising:
mounting a first device on a leadframe; and
mounting a second device on the leadframe;
wherein the leadframe has leads extending to the exterior of the package.

28. The method of claim 27 wherein the first device is mounted using the anvil of claim 23.
